(19) United States
(12) Patent Application Publication
(10) Pub. No.: US 2026/0013398 A1
(43) Pub. Date: Jan. 8, 2026

(54) SEMICONDUCTOR DEVICE AND METHOD FOR FABRICATING THE SAME

(71) Applicant: SK hynix Inc., Icheon-si (KR)

(72) Inventors: Jung Hyeok KWAK, Icheon-si (KR); Tae Yup KIM, Icheon-si (KR); Ku Youl JUNG, Icheon-si (KR); Jin Won JUNG, Icheon-si (KR)

(21) Appl. No.: 18/953,744

(22) Filed: Nov. 20, 2024

(30) Foreign Application Priority Data
Jul. 3, 2024 (KR) 10-2024-0087440

(51) Int. Cl. H10N 50/01; G11C 11/16; H10N 50/10; H10N 50/85

(52) U.S. Cl. CPC H10N 50/01; H10N 50/10; H10N 50/85; G11C 11/161

(57) ABSTRACT

Semiconductor devices and fabrication methods are disclosed. In an embodiment, a semiconductor device includes: a magnetic tunnel junction (MTJ) structure that comprises: a pinned layer having a fixed magnetization direction; a tunnel barrier layer formed adjacent to the pinned layer; and a free layer formed adjacent to the tunnel barrier layer and having a changeable magnetization direction. The free layer comprises: a first magnetic layer formed adjacent to the tunnel barrier layer; and a second magnetic layer formed adjacent to the first magnetic layer to be spaced apart from the tunnel barrier layer and including nano-pores within the second magnetic layer.

### CROSS-REFERENCE TO RELATED APPLICATIONS

The patent document claims the priority and benefits of Korean Patent Application No. 10-2024-0087440, filed on Jul. 3, 2024, in the Korean Intellectual Property Office, which is incorporated herein by reference in its entirety.

### TECHNICAL FIELD

The technology disclosed in this patent document relates to a semiconductor device including a magnetic tunnel junction (MTJ) structure, and a method for fabricating the same.

### BACKGROUND

As electronic devices become faster and more energy-efficient, memory devices embedded in the electronic devices are also required to have fast read/write operations and low operation voltages. Magnetic memory devices are being researched as memory solutions that satisfy these requirements. Magnetic memory devices are nonvolatile memory devices that retain data even after power supply is cut off. Due to their ability to operate at high speeds, the magnetic memory devices are gaining attention as the next-generation memory devices.

### SUMMARY

The disclosed technology can be implemented in some embodiments to provide a semiconductor device that includes a magnetic tunnel junction structure that can reduce saturation magnetization of a storage layer while preventing agglomeration that may occur due to a decrease in the thickness of the storage layer, without introducing an additional element, by forming a magnetic layer having a nano-pore structure inside the storage layer. The disclosed technology can also be implemented in some embodiments to provide a method for fabricating the same.

In an embodiment of the disclosed technology, a semiconductor device includes: a magnetic tunnel junction (MTJ) structure that comprises: a pinned layer having a fixed magnetization direction; a tunnel barrier layer formed adjacent to the pinned layer; and a free layer formed adjacent to the tunnel barrier layer and having a changeable magnetization direction, and the free layer includes: a first magnetic layer formed adjacent to the tunnel barrier layer; and a second magnetic layer formed adjacent to the first magnetic layer to be spaced apart from the tunnel barrier layer and including nano-pores within the second magnetic layer.

In another embodiment of the disclosed technology, a method for fabricating a semiconductor device including a magnetic tunnel junction structure that includes a free layer comprises: forming the free layer by sequentially stacking a first magnetic layer and a second magnetic layer over each other to be adjacent to a tunnel barrier layer, wherein the second magnetic layer is formed to include a plurality of nano-pores within the second magnetic layer.

### BRIEF DESCRIPTION OF THE DRAWINGS

FIG. 1 is a cross-sectional view illustrating an example of a magnetic tunnel junction structure included in a semiconductor device and a fabrication method thereof based on an embodiment of the present disclosure.

FIGS. 2A-2C are conceptual diagrams illustrating an example of the formation of a second magnetic layer having a nano-pore structure in a magnetic tunnel junction structure included in a semiconductor device, and a formation mechanism of a polymer-metal composite used in the formation of the second magnetic layer based on an embodiment of the present disclosure.

FIG. 3 is a cross-sectional view illustrating an example of a unit memory cell of a semiconductor device based on an embodiment of the present disclosure.

### DETAILED DESCRIPTION

Hereinafter, the various embodiments of the disclosed technology will be described in detail with reference to the attached drawings.

The drawings are not necessarily to scale and in some instances, proportions may have been exaggerated in order to clearly illustrate features of the embodiments. When a first layer is referred to as being ‘on’ a second layer or ‘on’ a substrate, it not only refers to a case where the first layer is formed directly on the second layer or the substrate but also a case where a third layer exists between the first layer and the second layer or the substrate.

The disclosed technology can be implemented in some embodiments to provide a semiconductor device that includes a magnetic tunnel junction structure including a magnetic layer with a nano-pore structure, and a method for fabricating the semiconductor device.

Magnetic memory devices may operate at relatively low voltages and have fast access times, significantly offsetting the shortcomings of traditional flash memory devices.

The storage layer SL of a magnetic tunnel junction may function as a data storage layer, and many of its characteristics change depending on the saturation magnetization value Ms of the magnetic material used therein. To ensure stable data storage, a magnetic material with a sufficient saturation magnetization is required. However, if saturation magnetization increases excessively, it can lead to an increase in the write error rate (WER) and interference between memory cells due to magnetic leakage. Therefore, various technologies are being developed to reduce the saturation magnetization of the magnetic material.

Simply reducing the thickness of the storage layer to decrease the saturation magnetization of the storage layer is not desirable because agglomeration can occur due to a decrease in the thickness of a metal layer. Another approach involves adding elements such as molybdenum (Mo) and tungsten (W) within the storage layer to form a magnetic dead layer, but there is a concern that a switching current (e.g., Ic) may increase due to heavy metal doping. To address these issues, the disclosed technology can be implemented in some embodiments to provide a method that may reduce the saturation magnetization of the storage layer without introducing an additional element.

Saturation magnetization is an intrinsic property of a material, and it is not easy to control the saturation magnetization of a track according to the conventional technology. In a semiconductor device based on an embodiment of the disclosed technology, a magnetic tunnel junction structure may easily decrease the effective saturation magnetization of the entire track without decreasing the thickness of a storage layer by forming a nano-pore structure in a second magnetic layer. In an embodiment, the storage layer may be a free layer having a changeable magnetization direction to represent different data by different directions of its magnetization relative to the fixed magnetization of another pinned layer. The semiconductor device based on an embodiment of the disclosed technology may include a specific structure that can significantly decrease the saturation magnetization while maintaining a Perpendicular Magnetic Anisotropy (PMA), thereby reducing the magnetostatic interaction, and thus reducing the influence of a leakage magnetic field.

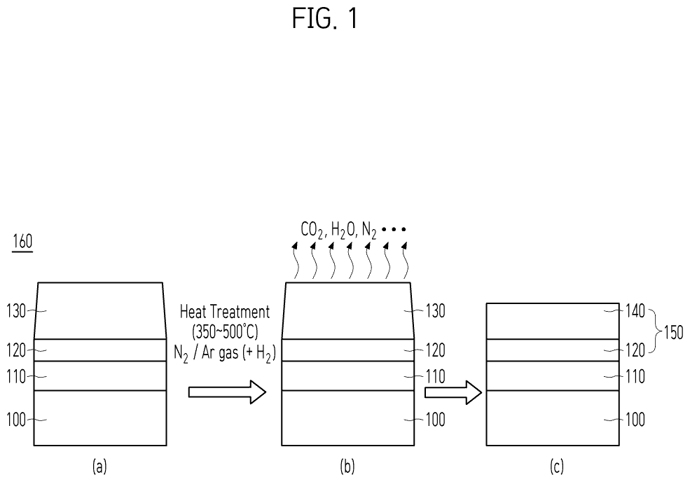

FIG. 1 is a cross-sectional view illustrating a magnetic tunnel junction structure included in a semiconductor device and a fabrication method thereof based on an embodiment of the disclosed technology.

FIG. 1A shows that a pinned layer 100 having a fixed magnetization direction; a tunnel barrier layer 110 formed adjacent to the pinned layer; and a free layer 150 formed adjacent to the tunnel barrier layer and having a changeable magnetization direction. The pinned layer 100 having a fixed magnetization direction may be formed adjacent to or at one side of the tunnel barrier layer 110. For example, the magnetization direction of the pinned layer 100 can remain fixed regardless of the program current passing through the pinned layer 100. The pinned layer 100 may have a perpendicular magnetic anisotropy (PMA) that is perpendicular to the pinned layer 100. For example, the pinned layer 100 may have an easy axis of magnetization in a direction perpendicular to the extension direction of the pinned layer 100. The pinned layer 100 may be a single layer or a multi-layer structure.

The pinned layer 100 may be formed by a magnetron sputtering process or an ultra-high vacuum (UHV) sputtering process and may function as a reference layer RL for magnetic junctions. Also, the pinned layer 100 may function as a space charge layer SCL, which is a region where impurities doped into the semiconductor are ionized.

The pinned layer 100 may include a ferromagnetic substance. For example, the pinned layer 100 may include at least one of an amorphous rare earth element alloy, a multi-layer thin film in which a magnetic metal and a non-magnetic metal are alternately stacked, an alloy with an L10 type crystalline structure, a cobalt-based alloy, and a combination of two or more of the aforementioned elements. The amorphous rare earth element alloys may include an alloy such as TbFe, TbCo, TbFeCo, DyTbFeCo, GdTbCo, or others. The multi-layer thin film in which a magnetic metal and a non-magnetic metal are alternately stacked may include, for example, Co/Pt, Co/Pd, CoCr/Pt, Co/Ru, Co/Os, Co/Au, Ni/Cu, or others. The alloy having the L10 type crystalline structure may include, for example, Fe₅₀Pt₅₀, Fe₅₀Pd₅₀, Co₅₀Pt₅₀, Fe₃₀Ni₂₀Pt₅₀, Co₃₀Ni₂₀Pt₅₀ or others. The cobalt-based alloy may include, for example, CoCr, CoPt, CoCrPt, CoCrTa, CoCrPtTa, CoCrNb, CoFeB or others. Also, the pinned layer 100 may include a CoFeB single layer.

Subsequently, a tunnel barrier layer TB 110 may be formed over the pinned layer 100. The tunnel barrier layer 110 may be disposed between the pinned layer 100 and the first magnetic layer 120 and may function as a dielectric tunnel barrier that causes quantum mechanical tunneling.

The tunnel barrier layer 110 may include, for example, at least one of magnesium oxide (MgOₓ, where x ranges from 1 to 2), or magnesium aluminum oxide (MgAlₓO_{y}, where x ranges from 1 to 2 and y ranges from 2 to 4), but the disclosed technology are not limited thereto.

Subsequently, a first magnetic layer 120 and a second magnetic layer 140 may be sequentially stacked over the tunnel barrier layer 110 to collectively form a free layer 150 having a changeable magnetization direction. In operation, the magnetization direction of the free layer 150 may vary or change depending on the program current passing through the free layer 150. The free layer 150 may have a perpendicular magnetic anisotropy (PMA) in some implementations: for example, the free layer 150 may have an easy axis of magnetization in a direction perpendicular to the extension direction of the free layer 150. The magnetization directions of the pinned layer 100 and the free layer 150 may be opposite to each other or aligned in the same direction.

The above different relative directions of the pinned layer 100 and the free layer 150 can be used to represent different data. For example, the magnetic tunnel junction structure 160 may have a low resistance and may store it as data “0” when the magnetization directions of the pinned layer 100 and the free layer 150 are aligned (e.g., the same direction). Conversely, when the magnetization directions of the pinned layer 100 and the free layer 150 are opposite to each other, the magnetic tunnel junction structure 160 may have a high resistance and may store it as data “1.” This phenomenon may be called a tunneling magneto-resistance (TMR). By applying this tunneling magneto-resistance phenomenon, the magnetic tunnel junction structure 160 may be used in a semiconductor memory device. The magnetization direction of the free layer 150 may be altered or changed by a spin transfer torque (STT).

The free layer 150 may include a first magnetic layer 120 and a second magnetic layer 140. First, the first magnetic layer 120 may be formed over the tunnel barrier layer 110, and then a polymer-metal composite layer 130 may be formed. The first magnetic layer 120 may be deposited thinly to achieve coherent tunneling with the tunnel barrier layer 110. Aligning the crystalline orientations of the tunnel barrier layer 110 and the first magnetic layer 120 increases the magneto-resistance (MR) ratio of a free tunnel junction cell.

The first magnetic layer 120 may be a sputtering thin film that is formed by a sputtering deposition process. The first magnetic layer 120 may include at least one material selected from a group including Co, Fe, Ni, NiO, Nb₂O₅, TiO₂, Al₂O₃, V₂O₅, WO₃, ZnO, and CoO. The first magnetic layer 120 may have a perpendicular magnetic anisotropy (PMA). The first magnetic layer 120 may have a saturation magnetization of approximately 1,500 emu/cc or less.

Subsequently, the polymer-metal composite layer 130 may be formed by coating the first magnetic layer 120 with a polymer-metal composite. The second magnetic layer 140 formed from the polymer-metal composite layer 130 may be spaced apart from the tunnel barrier layer 110 with the first magnetic layer 120 interposed therebetween.

In addition, the coating of the first magnetic layer 120 with the polymer-metal composite may be performed using a precursor solution that is prepared by dissolving a polymer and a metal precursor in an organic solvent. The polymer may be selected from a group including polyacetylene, polyethyleneimine (PEI), polystyrene (PS), polycaprolactone (PCL), poly(methyl methacrylate) (PMMA), polyethylene terephthalate (PET), and a copolymer of two or more of PEI, PS, PCL, PMMA, and PET. The metal precursor may be selected from a group including FeCl₃, CoCl₂, NiCl₂, Fe(NO₃)₃, Co(NO₃)₂, Ni(NO₃)₂, and a mixture of two or more of FeCl₃, CoCl₂, NiCl₂, Fe(NO₃)₃, Co(NO₃)₂, and Ni(NO₃)₂. The organic solvent may be selected from a group including acetone, toluene, n-hexane, cyclohexane, tetrahydrofuran (THF), acetonitrile, pyridine, and a mixture of two or more of acetone, toluene, n-hexane, cyclohexane, THF, acetonitrile, pyridine.

The precursor solution of the polymer-metal composite that is prepared as described above may be spin-coated on the first magnetic layer 120, and the organic solvent may be dried in an inert gas atmosphere. Spin coating is a wet method using a solution in which the precursor solution is dispersed in an appropriate solvent. In this case, it is desirable to control the spinning speed in the range of approximately 200 to 3,500 rpm. However, the spinning speed may not be limited thereto and may vary according to the type and the coating thickness of the polymer-metal composite to be coated. In some implementations, inert gases such as nitrogen (N₂) gas, argon (Ar) gas, helium (He) gas, neon (Ne) gas, krypton (Kr) gas, xenon (Xe) gas, and others may be used for an inert gas atmosphere. In one example, nitrogen (N₂) gas and/or argon (Ar) gas may be used.

In some implementations, the organic solvent may be dried and removed in the inert gas atmosphere for approximately 1 hour. In one example, the organic solvent may be dried and removed in the inert gas atmosphere for approximately 30 minutes. In some implementations, inert gases such as nitrogen (N₂) gas, argon (Ar) gas, helium (He) gas, neon (Ne) gas, krypton (Kr) gas, xenon (Xe) gas, and others may be used for an inert gas atmosphere. In one example, nitrogen (N₂) gas and/or argon (Ar) gas may be used. The organic solvent may be removed at a temperature ranging from the room temperature (25° C.) to approximately 60° C. When the organic solvent is removed, the polymer-metal composite layer 130 may be formed over the first magnetic layer 120.

Referring to FIG. 1B, a heat treatment may be performed to selectively decompose the polymer in the polymer-metal composite layer 130 and form a nano-pore structure in the second magnetic layer 140. The heat treatment may be performed at a temperature of approximately 350 to 500° C. in the inert gas atmosphere. In some implementations, inert gases such as nitrogen (N₂) gas, argon (Ar) gas, helium (He) gas, neon (Ne) gas, krypton (Kr) gas, xenon (Xe) gas, and others may be used for an inert gas atmosphere. In one example, nitrogen (N₂) gas and/or argon (Ar) gas may be used. When the heat treatment is performed at a temperature lower than approximately 350° C., the polymer may not be sufficiently decomposed. This may increase the concentration of impurities, which is not preferable. When the heat treatment is performed at a temperature higher than approximately 500° C., diffusion and aggregation of the metals inside the magnetic tunnel junction structure may be induced, which is not preferable.

When the heat treatment is performed, the ligand attached to the polymer and the composite may be decomposed, generating carbon dioxide (CO₂), nitrogen (N₂) gas, and water molecules (H₂O), which may be evaporated into a gaseous state and removed from the polymer-metal composite layer 130 in a gaseous state. The heat treatment may be performed in the presence of hydrogen gas to prevent oxidation of the metal embedded in the second magnetic layer 140. Hydrogen gas may react with oxygen to generate water molecules, allowing the oxygen to be removed. In an embodiment, hydrogen gas is added in a concentration range of approximately 3 to 10%.

Referring to FIG. 1C, through the processes of FIGS. 1A to 1C, the second magnetic layer 140 having the nano-pore structure that includes a plurality of pores in the thin film may be formed over the first magnetic layer 120. In other words, the second magnetic layer 140 having the nano-pore structure may be formed by: coating the first magnetic layer 120 with a polymer-metal composite; coating and drying the polymer-metal composite; and performing a heat treatment to decompose the polymer in the polymer-metal composite. The ligand attached to the polymer and the composite may be decomposed, forming a plurality of nano-pores in the places where the ligand is decomposed, and only metal species may be embedded in the second magnetic layer 140. Here, the free layer 150 including the first magnetic layer 120 and the second magnetic layer 140 having the nano-pore structure may function as a storage layer.

As the sintering temperature increases during the sintering of the magnetic material, particle growth occurs, reducing the specific surface area and porosity, which leads to an increase in the saturation magnetization. Conversely, as the sintering temperature decreases, particle growth is inhibited, causing an increase in the specific surface area and porosity, resulting in a decrease in the saturation magnetization. According to this principle, the second magnetic layer 140 having the nano-pore structure based on an embodiment of the disclosed technology may have increased porosity and reduced density, which may eventually lead to a decrease in the saturation magnetization of the free layer 150 that includes the second magnetic layer 140. In other words, a reduction in the saturation magnetization of the free layer 150 may be achieved, similar to when the thickness of the free layer 150 is decreased, without causing agglomeration due to a decrease in the thickness of the free layer 150 and without introducing an additional element.

In an embodiment of the disclosed technology, the free layer 150 of the magnetic tunnel junction structure 160 may be formed by stacking the first magnetic layer 120 having few pores and a relatively high density, and the second magnetic layer 140 having numerous pores and a relatively low density. In one example, the second magnetic layer 140 includes a greater number of pores than the first magnetic layer 120. Accordingly, the saturation magnetization may be decreased by approximately 50% or more without decreasing the thickness of the free layer 150. For example, the saturation magnetization of the free layer 150 may be approximately 500 emu/cc or less.

The thickness of the second magnetic layer 140 may be greater than the thickness of the first magnetic layer 120. While the first magnetic layer 120 is deposited thinly to achieve coherent tunneling, the second magnetic layer 140 may be formed relatively thicker than the first magnetic layer 120 due to its nano-pore structure, allowing the thickness of the second magnetic layer 140 to be greater than the thickness of the first magnetic layer 120. The thickness of the second magnetic layer 140 may be controlled by adjusting the concentration and the coating conditions of the polymer-metal composite.

The second magnetic layer 140 may include a magnetic material that is doped with a non-magnetic metal to decrease the saturation magnetization. For example, the magnetic material may include at least one element selected from a group including iron (Fe), cobalt (Co), and nickel (Ni), and the non-magnetic metal may include at least one element selected from a group including tungsten (W), molybdenum (Mo), tantalum (Ta), aluminum (Al), and magnesium (Mg).

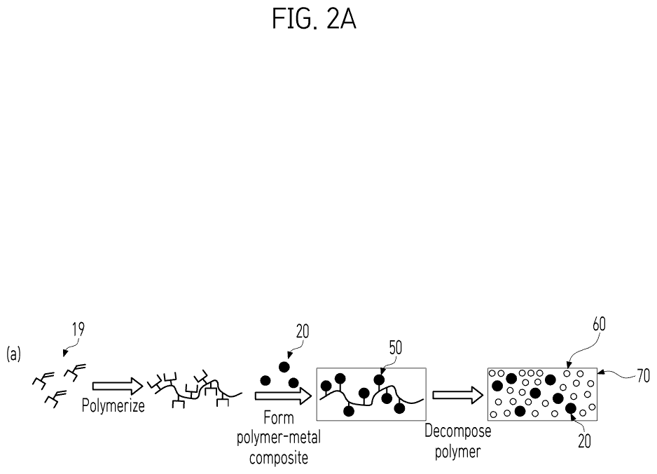

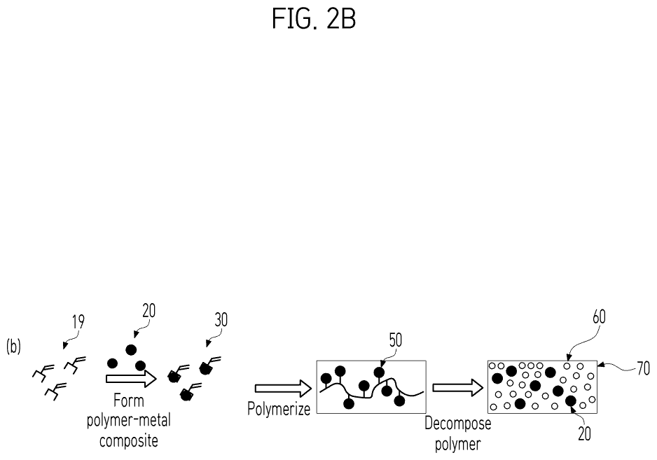

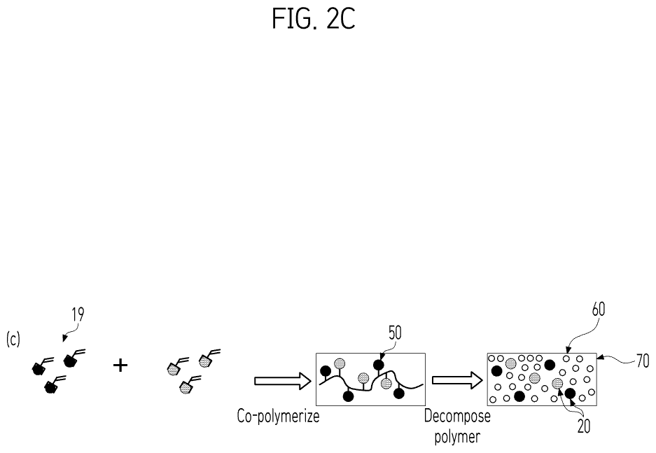

FIGS. 2A-2C are conceptual diagrams illustrating an example of the formation of the second magnetic layer 140 having a nano-pore structure and a formation mechanism of the polymer-metal composite used in the formation of the second magnetic layer 140. In an embodiment of the disclosed technology, the nano-pore structure 70 of a polymer-metal composite 50 and the second magnetic layer 140 may be formed according to the mechanisms illustrated in FIGS. 2A to 2C, but the disclosed technology is not limited by what is in FIGS. 2A-2C.

Referring to FIG. 2A, first, a ligand-bonded monomer 10 may be polymerized to form a ligand-bonded polymer 40, and then the polymer-metal composite 50 may be formed by reacting a metal species 20 with the ligand-bonded polymer 40. Referring to FIG. 2B, the ligand-bonded monomer 10 may be bonded to the metal species 20 to form a monomer-metal composite 30, and then these are polymerized to form the polymer-metal composite 50. Referring to FIG. 2C, two or more metal species 20 may be bonded to the ligand-bonded monomer 10 to form the monomer-metal composite 30 containing metals of two or more species, and then these are co-polymerized to form the polymer-metal composite 50 containing metals of two or more species.

The polymer-metal composite 50 containing metals of one or more species illustrated in FIGS. 2A to 2C may be selectively decomposed into the polymer and the ligand of the polymer-metal composite 50 through a heat treatment, and innumerable nano-pores 60 may be formed in the places where the polymer and the ligand are removed. In this way, the nano-pore structure 70 in which a plurality of nano-pores 60 are disposed between the metal species 20 may be formed inside the second magnetic layer 140. Accordingly, the formed second magnetic layer 140 may include a plurality of pores and have a relatively lower density than the first magnetic layer 120.

As a result of the process described above, in an embodiment of the disclosed technology, a magnetic tunnel junction structure 160 in which the second magnetic layer 140 having the nano-pore structure is disposed over the first magnetic layer 120 over a substrate may be formed. However, the disclosed technology are not limited thereto, and in another embodiment of the disclosed technology, a magnetic tunnel junction structure 160 in which the second magnetic layer 140 having the nano-pore structure is disposed below the first magnetic layer 120 and over the substrate may also be formed.

In some embodiments of the disclosed technology, a semiconductor device includes the magnetic tunnel junction structure 160 in which the second magnetic layer 140 having the nano-pore structure is formed over the first magnetic layer 120. In some embodiments of the disclosed technology, a semiconductor device includes the magnetic tunnel junction structure 160 in which the second magnetic layer 140 having the nano-pore structure is formed below the first magnetic layer 120. Through all of these embodiments, all the advantages described above may be achieved.

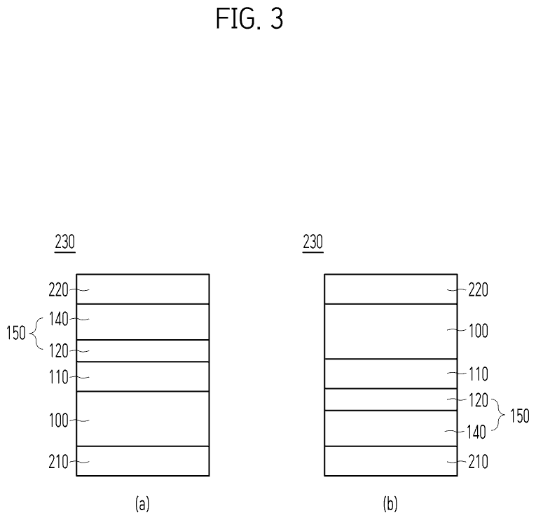

FIG. 3 is a cross-sectional view illustrating a unit memory cell 230 of a semiconductor device based on an embodiment of the disclosed technology.

The unit memory cells 230 may be arranged in two dimensions or three dimensions. The unit memory cells 230 may be respectively coupled to the intersections between the word lines and the bit lines. Accordingly, the unit memory cells 230 coupled to the word lines may be coupled to a read/write circuit by the bit lines.

The unit memory cell 230 based on an embodiment of the disclosed technology may include a lower electrode 210 and an upper electrode 220 in addition to the magnetic tunnel junction structure 160. The lower electrode 210 and the upper electrode 220 may be formed by a sputtering method, an electron beam deposition method, and a Chemical Vapor Deposition method. The lower electrode 210 and the upper electrode 220 may be formed of the same material.

Referring to FIG. 3A, the pinned layer 100 may be disposed between the lower electrode 210 and the tunnel barrier layer 110, and the free layer 150 including the first magnetic layer 120 and the second magnetic layer 140 of the nano-pore structure may be disposed between the tunnel barrier layer 110 and the upper electrode 220. Here, the lower electrode 210; the magnetic tunnel junction structure 160 in which the pinned layer 100, the tunnel barrier layer 110, and the free layer 150 are sequentially stacked; and the upper electrode 220 may be sequentially stacked over the upper surface of a lower electrode contact.

Also, referring to FIG. 3B, the pinned layer 100 may be disposed between the upper electrode 220 and the tunnel barrier layer 110, and the free layer 150 including the first magnetic layer 120 and the second magnetic layer 140 of the nano-pore structure may be disposed between the tunnel barrier layer 110 and the lower electrode 210. Here, the lower electrode 210; the magnetic tunnel junction structure 160 in which the free layer 150, the tunnel barrier layer 110, and the pinned layer 100 are sequentially stacked; and the upper electrode 220 may be sequentially stacked over the upper surface of the lower electrode contact.

Since the unit memory cell 230 based on an embodiment of the disclosed technology includes the magnetic tunnel junction structure 160 of the above-described embodiment of the disclosed technology, all the advantages mentioned above may be achieved.

In an embodiment of the disclosed technology, it is possible to reduce the saturation magnetization of a storage layer without causing agglomeration due to a decrease in the thickness of the storage layer without introducing an additional element, thereby reducing the write error rate of a magnetic tunnel junction structure and interference between the memory cell structures.

The embodiments and implementations disclosed above are examples only, and thus various enhancements and variations to the disclosed embodiments and implementations and other embodiments and implementations can be made based on what is described and illustrated in this patent document.

What is claimed is:

1. A semiconductor device, comprising:
a magnetic tunnel junction (MTJ) structure, comprising:
a pinned layer having a fixed magnetization direction;
a tunnel barrier layer formed adjacent to the pinned layer; and
a free layer formed adjacent to the tunnel barrier layer and having a changeable magnetization direction, and
wherein the free layer comprises:
a first magnetic layer formed adjacent to the tunnel barrier layer; and
a second magnetic layer formed adjacent to the first magnetic layer to be spaced apart from the tunnel barrier layer and including nano-pores within the second magnetic layer.

2. The semiconductor device of claim 1, wherein the second magnetic layer exhibits a lower density than the first magnetic layer.

3. The semiconductor device of claim 1, wherein the first magnetic layer is disposed over a substrate, and the second magnetic layer including nano-pores is disposed over or below the first magnetic layer.

4. The semiconductor device of claim 1, wherein the second magnetic layer includes a magnetic material that is doped with a non-magnetic metal.

5. The semiconductor device of claim 4, wherein the magnetic material includes at least one element selected from a group including iron (Fe), cobalt (Co), and nickel (Ni).

6. The semiconductor device of claim 4, wherein the non-magnetic metal includes at least one element selected from a group including tungsten (W), molybdenum (Mo), tantalum (Ta), aluminum (Al), and magnesium (Mg).

7. The semiconductor device of claim 1, wherein a saturation magnetization value of the free layer is approximately 500 emu/cc or less.

8. The semiconductor device of claim 1, wherein a thickness of the second magnetic layer is greater than a thickness of the first magnetic layer.

9. The semiconductor device of claim 1, wherein magnetization directions of the pinned layer and the free layer are opposite to each other.

10. The semiconductor device of claim 1, wherein magnetization directions of the pinned layer and the free layer are the same.

11. A method for fabricating a semiconductor device including a magnetic tunnel junction structure that includes a free layer, comprising:
forming the free layer by sequentially stacking a first magnetic layer and a second magnetic layer over each other to be adjacent to a tunnel barrier layer,
wherein the second magnetic layer is formed to include a plurality of nano-pores within the second magnetic layer.

12. The method of claim 11, wherein the first magnetic layer is formed by a sputtering deposition.

13. The method of claim 11, wherein forming the second magnetic layer that includes the nano-pores includes:
coating the first magnetic layer with a polymer-metal composite;
drying the polymer-metal composite; and
performing a heat treatment to decompose a polymer in the polymer-metal composite.

14. The method of claim 13, wherein the coating of the first magnetic layer with the polymer-metal composite is performed by using a precursor solution formed by dissolving a polymer and a metal precursor in an organic solvent.

15. The method of claim 14, wherein the polymer is selected from a group including polyacetylene, polyethyleneimine (PEI), polystyrene (PS), polycaprolactone (PCL), poly (methyl methacrylate) (PMMA), polyethylene terephthalate (PET), and a copolymer of two or more of the PEI, PS, PCL, PMMA and PET.

16. The method of claim 14, wherein the metal precursor is selected from a group including FeCl₃, CoCl₂, NiCl₂, Fe(NO₃)₃, Co(NO₃)₂, Ni(NO₃)₂, and a mixture of two or more of the FeCl₃, CoCl₂, NiCl₂, Fe(NO₃)₃, Co(NO₃)₂, and Ni(NO₃)₂.

17. The method of claim 14, wherein the organic solvent is selected from a group including acetone, toluene, n-hexane, cyclohexane, tetrahydrofuran (THF), acetonitrile, pyridine, and a mixture of two or more of the acetone, toluene, n-hexane, cyclohexane, tetrahydrofuran (THF), acetonitrile, and pyridine.

18. The method of claim 13, wherein the heat treatment is performed at a temperature of approximately 350 to 500° C. in an inert gas atmosphere.

19. The method of claim 13, wherein the polymer-metal composite is formed by:
polymerizing a ligand-bonded monomer to form a ligand-bonded polymer; and reacting the ligand-bonded polymer with a metal species to form a polymer-metal composite.

20. The method of claim 13, wherein the polymer-metal composite is formed by:
reacting a ligand-bonded monomer with one or more metal species to form a monomer-metal composite; and polymerizing or co-polymerizing the monomer-metal composite to form a polymer-metal composite.
